(19) United States
(12) Patent Application Publication
(10) Pub. No.: US 2026/0372142 A1
(43) Pub. Date: Nov. 19, 2026

(54) CERAMIC SUBSTRATE FOR POWER MODULE AND POWER MODULE COMPRISING SAME

(71) Applicant: AMOGREENTECH CO., LTD., Gimpo-si, Gyeonggi-do (KR)

(72) Inventors: Ji-Hyung LEE, Gimpo-si, Gyeonggi-do (KR); Hyo Jin PARK, Gimpo-si, Gyeonggi-do (KR)

(21) Appl. No.: 19/143,362

(22) PCT Filed: Dec. 21, 2023
(86) PCT No.: PCT/KR2023/021330

§ 371 Date: Jun. 25, 2025

(30) Foreign Application Priority Data
Dec. 29, 2022 (KR) 10-2022-0189757

(51) Int. Cl. H10W 70/652; H10W 70/66; H10W 70/68; H10W 90/00

(52) U.S. Cl. CPC H10W 70/6528; H10W 70/681; H10W 90/401; H10W 70/66

(57) ABSTRACT

A ceramic substrate for a power module is provided. A ceramic substrate for a power module, according to one embodiment of the present invention, comprises: a ceramic base; at least one electrode pattern which includes a metal layer and which is formed on the ceramic base; and a spacer which is disposed on the electrode pattern, wherein the metal layer has an accommodating portion that accommodates the spacer, and at least one end portion of the spacer is accommodated in the accommodating portion. According to this, the present invention can suppress thermal shock due to thermal expansion caused of heat generation or during spacer joining, has excellent interlayer adhesion, maintains the distance between ceramic substrates such that a semiconductor chip is not separated from the electrode pattern, and can effectively transfer semiconductor chip heat to the ceramic substrate, thereby improving the heat dissipation performance of the power module.

### TECHNICAL FIELD

The present invention relates to a ceramic substrate for a power module, and more specifically to a ceramic substrate for a power module, which can suppress thermal shock due to thermal expansion during spacer bonding or other heat generation, has excellent interlayer bonding strength, maintains a distance between ceramic substrates such that a semiconductor chip is not separated from an electrode pattern, and can effectively transfer heat from the semiconductor chip to the ceramic substrate, thereby improving the heat dissipation performance of the power module, and a power module including the same.

### BACKGROUND ART

Due to environmental issues and the depletion of fossil fuels, interest in and development of hybrid and electric vehicles are increasing. These eco-friendly vehicles are equipped with power conversion devices such as inverters or converters to convert power supplied from rechargeable batteries or fuel cells using hydrogen fuel into power for driving a motor.

These power conversion devices are equipped with power modules in which power semiconductor chips for power conversion are mounted.

Typically, power modules are composed of semiconductor chips made of insulated gate bipolar transistors (IGBTs), diodes, gallium nitride (GaN) and silicon carbide (SiC) mounted on a ceramic substrate.

The semiconductor chips provided on the power module generate a lot of heat during the power conversion process, and if the generated heat is not quickly dissipated, the characteristics of the semiconductor chips may deteriorate and they may not operate stably. Therefore, various types of heat dissipation means for power modules are being proposed.

Recently, in order to improve the heat dissipation performance of power modules, a power module with a double-side cooling method (DSC) has been proposed, which mounts a semiconductor chip between a pair of ceramic substrates and dissipates heat from both sides of the semiconductor chip. A power module with a double-side cooling method has a structure in which an electrode pattern is formed on one surface of each of a pair of substrates, and a semiconductor chip is mounted between a pair of electrode patterns facing each other. Since a heat sink can be installed on each ceramic substrate, the heat dissipation effect can be improved compared to the existing single-side cooling method.

However, in such a power module with a double-side cooling method, the support structure installed to maintain a separation distance between the ceramic substrates thermally expands due to the heat emitted from the semiconductor chip, and the distance between the ceramic substrates cannot be maintained constant, and thus, the semiconductor chip mounted between the ceramic substrates can be separated from the electrode pattern of the ceramic substrate.

Therefore, there is an urgent need to develop a ceramic substrate that has excellent interlayer bonding strength, can be mass-produced, and can prevent anion migration.

### DISCLOSURE

### Technical Problem

The present invention has been devised to solve the above-described conventional problems, and an object of the present invention is to provide a ceramic substrate for a power module, which can suppress thermal shock due to thermal expansion caused by spacer bonding or other heat generation, and has excellent interlayer bonding strength, and a power module including the same.

In addition, another object of the present invention is to provide a ceramic substrate for a power module, which can improve the heat dissipation performance of the power module by maintaining the distance between the ceramic substrates such that the semiconductor chip is not separated from the electrode pattern, and effectively transferring the heat of the semiconductor chip to the ceramic substrate.

### Technical Solution

In order to solve the above-described problems, the present invention provides a ceramic substrate for a power module, including a ceramic base; at least one electrode pattern that includes a metal layer and is formed on the ceramic base; and a spacer that is disposed on the electrode pattern, wherein the metal layer is formed with an accommodating portion that accommodates the spacer, and at least one end portion of the spacer is accommodated in the accommodating portion.

According to an embodiment of the present invention, a depth of the accommodating portion may be 50 to 80% of a thickness of the metal layer.

In addition, a depth at which the spacer may be accommodated in the accommodating portion is 8 to 63% of a total thickness of the spacer.

In addition, at least one end portion of the spacer may be brazed to the accommodating portion of the metal layer.

In addition, the spacer may be made of a Cu material or CPC material in which Cu, Cu—Mo (copper-molybdenum) and Cu are sequentially laminated.

In addition, the metal layer may include any one or more of Al and Cu.

In addition, the ceramic substrate may include any one or more of silicon nitride, aluminum nitride and aluminum oxide.

In addition, the present invention provides a power module, including a ceramic substrate including a first ceramic substrate and a second ceramic substrate, each of which is formed with an electrode pattern including a metal layer on at least one surface of the ceramic substrate; a semiconductor chip disposed between the first ceramic substrate and the second ceramic substrate, and electrically connected to the electrode pattern; and at least one spacer disposed between the first ceramic substrate and the second ceramic substrate, wherein any one or more of the metal layers of the first ceramic substrate and the second ceramic substrate is formed with an accommodating portion that accommodates the spacer, and at least one end portion of the spacer is accommodated in the accommodating portion.

According to an embodiment of the present invention, a metal layer of the first ceramic substrate may be formed with an accommodating portion that accommodates the spacer, and a metal layer of the second ceramic substrate may be formed with an accommodating portion that accommodates any one or more of the spacer and the semiconductor chip.

### Advantageous Effects

The ceramic substrate for a power module according to the present invention and the power module including the same can suppress thermal shock due to thermal expansion during spacer bonding or other heat generation, have excellent interlayer bonding strength, maintain the distance between ceramic substrates such that the semiconductor chip is not separated from the electrode pattern, and effectively transfer heat from the semiconductor chip to the ceramic substrate, thereby improving the heat dissipation performance of the power module.

### DESCRIPTION OF DRAWINGS

FIG. 1 is a cross-sectional schematic diagram of a ceramic substrate for a power substrate according to an embodiment of the present invention,

FIG. 2 is a cross-sectional schematic diagram of a power substrate according to an embodiment of the present invention, and

FIG. 3 is a cross-sectional schematic diagram of a power substrate according to another embodiment of the present invention.

### BEST MODE

Hereinafter, with reference to the attached drawings, embodiments of the present invention will be described in detail so that those skilled in the art can easily practice the present invention. The present invention may be implemented in various different forms and is not limited to the embodiments described herein. In order to clearly describe the present invention in the drawings, parts that are not related to the description are omitted, and the same reference numerals are assigned to the same or similar components throughout the specification.

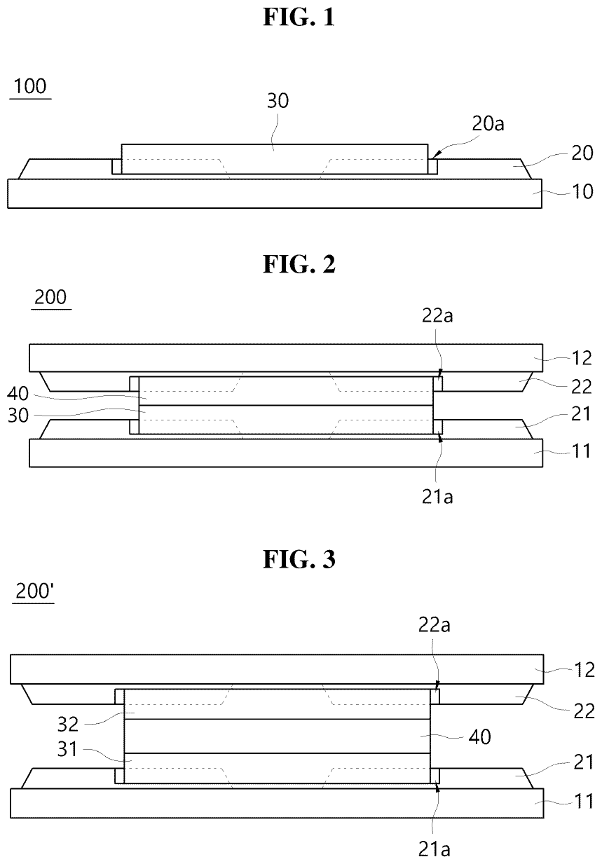

As shown in FIG. 1, a ceramic substrate 100 for a power module according to an embodiment of the present invention includes a ceramic base 10, at least one electrode pattern 20 formed on the ceramic base 10 including a metal layer, and a spacer 30 disposed on the electrode pattern 20, and the metal layer is implemented such that an accommodating portion 20a for receiving the spacer 30 is formed, and at least one end portion of the spacer 30 is accommodated in the accommodating portion 20a.

Hereinafter, each constitution of the ceramic substrate 100 for a power module will be described.

First of all, the ceramic base 10 will be described.

The ceramic base 10 may be a ceramic base having a predetermined surface roughness through surface modification, and accordingly, it may further strengthen the bonding strength with adjacent layers.

The surface modification may be, for example, a chemical treatment using a chemical agent or a physical treatment using polishing, sandblasting and the like to roughen the surface of the ceramic base 10 to form micro-protrusions, and in addition, it may also be modified into any other example that can impart a predetermined roughness to the surface of the ceramic base 10.

In addition, the ceramic base may include any one or more of silicon nitride, aluminum nitride and aluminum oxide, and preferably, it may be advantageous to be silicon nitride to achieve the objects of the present invention. In addition, the ceramic base may be sintered at a high temperature of 1,000 °C or higher.

Meanwhile, the ceramic base 10 may include nitrogen oxide, and accordingly, when a predetermined metal is deposited on the ceramic base 10, a metal nitride or metal oxide is formed at the interface, and thus, the interfacial bonding force may be excellent.

Next, the electrode pattern 20 will be described.

The electrode pattern 20 is formed on the ceramic base 10, and it may be formed by brazing and then etching metal foil made of a metal material to the ceramic base 10, or may be formed by first patterning a metal plate through mechanical processing and then brazing and bonding the same to the ceramic base 10. When it is implemented as power modules 200, 200′ as disclosed in FIGS. 2 and 3, a semiconductor chip 40 is disposed on the surface of the electrode patterns 21, 22 formed in this manner.

The metal layer forming the electrode pattern 20 may include any one or more of Al (aluminum) and Cu (copper) having excellent electrical and thermal conductivity, and it is more advantageous to include Cu to achieve the objects of the present invention.

Accordingly, the electrode patterns 20, 21, 22 may be electrically connected to the semiconductor chip 40 described below to transmit a control signal, and may quickly transfer heat generated from the semiconductor chip 40 to a heat sink (not shown) coupled to the ceramic bases 10, 11, 12 and the metal layers having volumes corresponding to the electrode patterns 20, 21, 22.

Meanwhile, as described above, the metal layers of the electrode patterns 20, 21, 22 are formed with accommodating portions 20a, 21a, 22a that accommodate the spacers 30, 31, 32 described below.

The depths of the accommodating portions 20a, 21a, 22a may be 50 to 80% of the thicknesses of the metal layers, and preferably 53 to 75% of the thicknesses of the metal layers. If the depth of the accommodating portion is less than 50% of the thickness of the metal layer, the thermal shock due to thermal expansion during spacer bonding or other heat generation may not be suppressed, and the interlayer bonding strength may be reduced, and if it is more than 80%, the semiconductor chip may be separated from the electrode pattern.

In addition, the areas of the accommodating portions 20a, 21a, 22a, preferably the horizontal length and the vertical length, may be greater than the lengths of the spacers 30, 31, 32 described below, and accordingly, it may be more advantageous in achieving the objects of the present invention.

Next, the spacers 30, 31, 32 will be described.

The spacers 30, 31, 32 are disposed on the electrode patterns 20, 21, 22 described above, and may be directly disposed on the ceramic bases 10, 11, 12 to be used as support structures. Alternatively, they are disposed in an area where a semiconductor chip 40 is mounted, or they are disposed on an electrode pattern 20 where a semiconductor chip 40 is not mounted.

The spacers 30, 31, 32 may be made of a Cu material or a CPC material in which Cu, Cu—Mo (copper-molybdenum) and Cu are sequentially laminated. The Cu material may be more advantageous in achieving the objects of the present invention when the material of the metal layer is Cu, and the CPC material may suppress thermal shock due to thermal expansion during spacer bonding or other heat generation due to a low coefficient of thermal expansion (CTE).

Meanwhile, when the spacers 30, 31, 32 are disposed between the ceramic bases 11, 12 in the power modules 200, 200′ described below as shown in FIGS. 2 and 3, the heat dissipation performance may be excellent because the heat from the semiconductor chip 40 is quickly transferred to the ceramic bases 11, 12 due to excellent thermal conductivity. In this case, the spacers 30, 31, 32 may be formed to correspond to the area of the semiconductor chip 40 mounted on the electrode patterns 20, 21, 22. If the area of the spacers 30, 31, 32 is smaller than the area of the semiconductor chip 40, it is difficult to expect effective heat dissipation, and if the area of the spacers 30, 31, 32 is excessively larger than the area of the semiconductor chip 40, an electrical short may occur due to interference with adjacent components. In addition, the spacers 30, 31, 32 may be brazed to the area of the electrode patterns 20, 21, 22 on which the semiconductor chip 40 is mounted, preferably to the accommodating portions 20a, 21a, 22. The brazing process is a method of interposing a filler layer between the spacers 30, 31, 32 and the electrode pattern 20 to bond at a working temperature of about 400 to 900 °C. In this case, the filler layer may be a structure in which it is one selected from Ag, Cu and AgCu, or two or more thereof are mixed. Ag, Cu and AgCu alloys have high thermal conductivity such that heat generated from the semiconductor chip 40 may be quickly transferred to the spacers 30, 31, 32. Since the brazing process is a process of bonding two base materials by applying heat that does not damage the base materials, it is possible to couple the spacers 30, 31, 32 on which the semiconductor chip 40 is mounted and the electrode pattern 20 while minimizing damage.

However, since thermal shock due to thermal expansion may occur during the brazing process, as described above, predetermined accommodating portions 20a, 21a, 22 are formed in the metal layer, and in this case, the depth at which the spacers 30, 31, 32 are accommodated in the accommodating portions 20a, 21a, 22 may be 8 to 63% of the total thickness of the spacer 30, 31, 32, and preferably 10 to 60%. If the depth at which the spacer is accommodated in the accommodating portion is less than 8% of the total thickness of the spacer, the thermal shock due to thermal expansion during spacer bonding or other heat generation may not be suppressed, the interlayer bonding strength may be reduced, and if it is more than 63%, the semiconductor chip may be separated from the electrode pattern.

The ceramic substrate 100 for a power module according to an embodiment of the present invention may be applied to a power module of a double-side cooling method in which a semiconductor chip formed of a material such as a diode, an insulated gate bipolar transistor (IGBT), a metal oxide semiconductor field effect transistor (MOSFET), a junction field effect transistor (JFET), a high electric mobility transistor (HEMT), silicon carbide (SiC) or gallium nitride (GaN) is mounted between two ceramic substrates. Power modules are used to supply high-voltage current for driving motors in hybrid vehicles, electric vehicles and the like, and power modules with double-sided cooling have superior cooling performance compared to single-sided cooling power modules with heat sinks on one side, and thus, they can be applied to high-output power modules.

The present invention includes ceramic bases 11, 12 including a first ceramic base 11 and a second ceramic base 12 that are respectively formed with electrode patterns 21, 22 including a metal layer formed on at least one surface of the ceramic bases 11, 12, a semiconductor chip 40 disposed between the first ceramic base 11 and the second ceramic base 12, and electrically connected to the electrode pattern 21, 22, and at least one spacer 30, 31, 32 disposed between the first ceramic base 11 and the second ceramic base 12, wherein any one or more of the metal layers of the first ceramic base 11 and the second ceramic base 12 is formed with accommodating portions 21a, 22a for accommodating the spacers 30, 31, 32, and at least one end portion of the spacers 30, 31, 32 provides power modules 200, 200′ accommodated in the accommodating portion 21a, 22a.

In this case, the metal layer of the first ceramic base 11 may be formed with an accommodating portion 21a that accommodates the spacers 30, 31, and the metal layer of the second ceramic base 12 may be formed with an accommodating portion 22a that accommodates any one or more of the spacers 30, 32 and the semiconductor chip 40.

Meanwhile, a separate bonding layer may be further included at the interface between the semiconductor chip 40 and the spacers 30, 31, 32 and/or the interface between the semiconductor chip 40 and the ceramic bases 11, 12.

The bonding layer is intended to improve the interlayer bonding strength and high-temperature reliability of the power modules 200, 200′, and any material of the bonding layer that can be commonly used in the art may be used without limitation, and preferably, it may include solder or silver paste. The solder may be made of a SnPb-based, SnAg-based, SnAgCu-based or Cu-based solder paste with high bonding strength and excellent high-temperature reliability. Compared to solder, silver paste has better high-temperature reliability and higher thermal conductivity. The silver paste may include 90 to 99 wt % of a Ag powder and 1 to 10 wt % of a binder to have high thermal conductivity, and the Ag powder may be nanoparticles. The Ag powder of nanoparticles has high bonding density and high thermal conductivity due to its high surface area.

Meanwhile, since a known detailed configuration may be applied to the detailed configuration of the power module, the present invention does not specifically limit the same.

Meanwhile, the ceramic substrate for a power module according to an embodiment of the present invention may be manufactured through the manufacturing method described below, but is not limited thereto.

The ceramic substrate for a power module may be manufactured by including bonding a metal layer on a ceramic base 10, etching the metal layer to form an electrode pattern 20, forming an accommodating portion 20a on the electrode pattern, and forming a spacer 30 in the accommodating portion 20a of the electrode pattern 20.

The step of bonding a metal layer may bond a metal layer made of a metal on a ceramic base 10 by an active metal brazing (AMB) process. The ceramic base 10 may be, for example, any one of alumina (Al₂O₃), AlN, SiN and Si₃N₄. The metal layer made of a metal may be brazed to the upper and lower surfaces of the ceramic base 10 by sintering at 780 °C to 1,100 °C. Such a substrate is called an active metal brazing (AMB) substrate.

Herein, the metal layer may be a copper material. Since copper has a thermal conductivity of 400 W/m·K, it may effectively dissipate heat generated from a semiconductor chip 40 and transferred through spacers 30, 31, 32.

The step of forming an electrode pattern may be performed by etching a metal layer bonded on a ceramic base 10 to fit a designed pattern to form an electrode pattern 20, and the step of forming an accommodating portion may be performed through etching.

The step of forming a spacer may be performed by brazing a spacer 30 to an area where a semiconductor chip is mounted in the electrode pattern 20. Brazing is a method of interposing a filler layer between the spacer 30 and the electrode pattern 20 to bond at an operating temperature of about 400 to 900 °C.

In this way, the method for manufacturing a ceramic substrate for a power module according to an embodiment of the present invention includes an accommodating portion at a location where a semiconductor chip is to be mounted, and by accommodating/attaching a spacer 30 to the accommodating portion, the precision during mounting of the semiconductor chip may be increased, and damage to the power module caused by thermal expansion due to heat generation of the semiconductor chip 40 may be minimized.

### MODES OF THE INVENTION

The present invention will be described more specifically through the following examples, but the following examples do not limit the scope of the present invention, and should be interpreted as helping the understanding of the present invention.

### Example 1

A 300 μm thick copper metal layer was bonded to a ceramic base, which is a silicon nitride (Si₃N₄) substrate with a thickness of 0.32 mm, by the active metal brazing bonding (AMB) method, and then, the upper part of the metal layer was processed (the horizontal and vertical bonding gaps of the spacer were designed to be 0.20 mm on average each) to form an accommodating portion for positional accuracy and easy bonding for spacer bonding, and the design was made by considering the thermal expansion coefficient of the metal layer during bonding. In order to form a metal electrode pattern, a photolithography process was used to form a metal electrode circuit portion through exposure, development and etching, and a single power substrate was manufactured through a brazing layer etching and laser scribing process, and then, the spacer of the gate part was bonded to the spacer by using an Ag sintering film according to the power module design criteria. In addition, the ceramic substrate for a power module was manufactured by bonding the spacer of a Cu material to the accommodating portion under the brazing condition. In this case, the depth of the accommodating portion compared to the thickness of the metal layer was 64%, and the depth accommodated in the accommodating portion was 35% compared to the total thickness of the spacer.

### Examples 2 to 9 and Comparative Example 1

These were manufactured in the same manner as Example 1, except that the depth of the accommodating portion compared to the thickness of the metal layer, the accommodated depth compared to the thickness of the spacer, and whether the accommodating portion was formed were changed to manufacture the ceramic substrates for power modules as shown in Tables 1 and 2 below.

### Experimental Example

The following physical properties were evaluated for each of the ceramic substrates for power modules manufactured according to the examples and comparative examples, and the results are shown in Tables 1 and 2.

### 1. Evaluation of Thermal Shock Due to Thermal Expansion

The thermal shock due to thermal expansion was evaluated for each of the ceramic substrates for power modules manufactured according to the examples and comparative examples using the brazing bonding method. In this case, the temperature was adjusted multiple times from −55 °C to 150 °C, and the number of times defects occurred was measured.

### 2 Evaluation of Interlayer Bonding Strength

For each ceramic substrate manufactured according to the examples and comparative examples, the interlayer bonding strength was evaluated according to ASTM D6862.

TABLE 1

| | Example | Example | Example | Example | Example |
|---|---|---|---|---|---|
| Classification | 1 | 2 | 3 | 4 | 5 |
| Depth of Accommodating | 64 | 45 | 53 | 75 | 85 |
| Portion Compared to | | | | | |
| Thickness of Metal Layer | | | | | |
| (%) | | | | | |
| Accommodated Depth | 35 | 35 | 35 | 35 | 35 |
| Compared to Thickness of | | | | | |
| Spacer (%) | | | | | |
| Whether the | Formed | Formed | Formed | Formed | Formed |
| Accommodating Portion Is | | | | | |
| Formed | | | | | |
| Evaluation of Thermal | 3,000 | 2,500 | 3,000 | 3,000 | 3,000 |
| Shock According to Thermal | times or | times | times or | times or | times or |
| Expansion (−55 °C to 150 °C) | more | | more | more | more |
| Evaluation of Interlayer | 15 N/mm | 15 N/mm | 15 N/mm | 15 N/mm | 12 N/mm |
| Bonding Strength | | | | | |

TABLE 2

| | Example | Example | Example | Example | Comparative |
|---|---|---|---|---|---|
| Classification | 6 | 7 | 8 | 9 | Example 1 |
| Depth of Accommodating | 64 | 64 | 64 | 64 | — |
| Portion Compared to | | | | | |
| Thickness of Metal Layer | | | | | |
| (%) | | | | | |
| Accommodated Depth | 5 | 10 | 60 | 68 | — |
| Compared to Thickness of | | | | | |
| Spacer (%) | | | | | |
| Whether the | Formed | Formed | Formed | Formed | Not |
| Accommodating Portion Is | | | | | formed |
| Formed | | | | | |
| Evaluation of Thermal | 2,600 | 3,000 | 3,000 | 3,000 | 1,500 |
| Shock According to Thermal | times | times or | times or | times or | times |
| Expansion (−55 °C to 150 °C) | | more | more | more | |
| Evaluation of Interlayer | 14 N/mm | 15 N/mm | 15 N/mm | 12 N/mm | 11 N/mm |
| Bonding Strength | | | | | |

As can be seen from Tables 1 and 2 above, it can be confirmed that Examples 1, 3, 4, 7 and 8, which satisfied all of the conditions of the depth of the accommodating portion compared to the metal layer thickness, the accommodated depth compared to the thickness of the spacer thickness, and whether the accommodating portion was formed according to the present invention, could simultaneously achieve the effects of suppressing thermal shock due to thermal expansion, significantly superior interlayer bonding strength, and significantly superior silver ion migration and heat dissipation performance, compared to Examples 2, 5, 6, 9 and Comparative Example 1, which did not satisfy even one of the above.

Although one embodiment of the present invention has been described above, the spirit of the present invention is not limited to the embodiments presented in the present specification, and those skilled in the art who understand the idea of the present invention will be able to easily propose other embodiments by modifying, changing, deleting or adding components within the scope of the same idea, but this will also be considered to fall within the scope of the spirit of the present invention.
[National Research and Development Projects Supporting This Invention]
[Project Identification Number] 1415181469
[Project Number] 20018920
[Name of Ministry] Ministry of Trade, Industry and Energy
[Name of Project Management (Specialized) Institution] Korea Industrial Technology Assessment and Management Institute
[Title of Research Project] Material and Component Technology Development Project (Package Type)
[Title of Research Task] Development of Silicon Nitride AMB (Active Metal Brazing) Circuit Board Manufacturing Technology for High-Power Power Modules of Electric Vehicles
[Contribution Ratio] 1/1
[Name of Project Executing Institution] Amogreentech Co., Ltd.
[Research Period] Jul. 1, 2022 to Dec. 31, 2026

1. A ceramic substrate for a power module, comprising:
a ceramic base;
at least one electrode pattern that comprises a metal layer and is formed on the ceramic base; and
a spacer that is disposed on the electrode pattern,
wherein the metal layer is formed with an accommodating portion that accommodates the spacer, and at least one end portion of the spacer is accommodated in the accommodating portion.

2. The ceramic substrate of claim 1, wherein a depth of the accommodating portion is 50 to 80% of a thickness of the metal layer.

3. The ceramic substrate of claim 1, wherein a depth at which the spacer is accommodated in the accommodating portion is 8 to 63% of a total thickness of the spacer.

4. The ceramic substrate of claim 1, wherein at least one end portion of the spacer is brazed to the accommodating portion of the metal layer.

5. The ceramic substrate of claim 1, wherein the spacer is made of a Cu material or CPC material in which Cu, Cu—Mo (copper-molybdenum) and Cu are sequentially laminated.

6. The ceramic substrate of claim 1, wherein the metal layer comprises any one or more of Al and Cu.

7. The ceramic substrate of claim 1, wherein the ceramic substrate comprises any one or more of silicon nitride, aluminum nitride and aluminum oxide.

8. A power module, comprising:
a ceramic substrate comprising a first ceramic substrate and a second ceramic substrate, each of which is formed with an electrode pattern comprising a metal layer on at least one surface of the ceramic substrate;
a semiconductor chip disposed between the first ceramic substrate and the second ceramic substrate, and electrically connected to the electrode pattern; and
at least one spacer disposed between the first ceramic substrate and the second ceramic substrate,
wherein any one or more of the metal layers of the first ceramic substrate and the second ceramic substrate is formed with an accommodating portion that accommodates the spacer, and at least one end portion of the spacer is accommodated in the accommodating portion.

9. The power module of claim 8, wherein a metal layer of the first ceramic substrate is formed with an accommodating portion that accommodates the spacer, and a metal layer of the second ceramic substrate is formed with an accommodating portion that accommodates any one or more of the spacer and the semiconductor chip.
